(19) United States
(12) Patent Application Publication
(10) Pub. No.: US 2014/0332034 A1
(43) Pub. Date: Nov. 13, 2014

(54) PROCESS COMPRISING WATER VAPOR FOR HAZE ELIMINATION AND RESIDUE REMOVAL

(71) Applicant: TEL FSI, Inc., Chaska, MN (US)

(72) Inventors: Jeffrey M. Lauerhaas, Waconia, MN (US); Don Kahaian, Eden Prairie, MN (US)

(73) Assignee: TEL FSI, Inc., Chaska, MN (US)

(21) Appl. No.: 14/255,570

(22) Filed: Apr. 17, 2014

Related U.S. Application Data
(60) Provisional application No. 61/820,919, filed on May 8, 2013.

(51) Int. Cl. H01L 21/67; H01L 21/02

(52) U.S. Cl. CPC H01L 21/67051; H01L 21/02041
USPC 134/28; 134/36

(57) ABSTRACT

A method of treating a substrate comprises removing material from a substrate using a treatment protocol to provide a treated substrate followed by a rinsing step. In the rinsing step at least one stream comprising a rinsing fluid is introduced and water vapor is caused to collide with and atomize the rinsing fluid. The atomized rinsing fluid is caused to rinsingly contact the treated substrate.

### CROSS-REFERENCE TO RELATED APPLICATIONS

This application claims the benefit of U.S. Provisional Application Ser. No. 61/820,919, filed May 8, 2013, entitled “PROCESS COMPRISING WATER VAPOR FOR HAZE ELIMINATION AND RESIDUE REMOVAL” which application is incorporated herein by reference in its entirety.

### FIELD OF THE INVENTION

The present invention relates to a selectively removing material from a substrate. More specifically, the present invention relates to a method comprising water vapor.

### BACKGROUND OF THE INVENTION

Advances in electronic technology cause integrated circuits to be formed on substrates such as silicon wafers with ever increasing packing density of active components. The formation of circuits is carried out by sequential application, processing, and removal, including selective removal, of various components from the substrate.

Various compositions have been developed for removal of specific classes of components from substrates in semiconductor wafer technologies. For example, a composition commonly denoted SC-1, which contains a mixture of NH₄OH (29wt %)/H₂O₂(30 wt %)/water at a volume ratio of about 1:1:5 (or at somewhat higher dilution ratios), is typically used to remove particles and to reoxidize hydrophobic silicon surfaces. Similarly, a composition commonly denoted SC-2, which contains a mixture of HCl (37 wt %)/H₂O₂(30 wt%)/water at a volume ratio of about 1:1:5 (or at somewhat higher dilution ratios), is typically used to remove metals. An additional composition, commonly called a Piranha composition, comprises H₂SO₄(98 wt %)/H₂O₂(30 wt%) at a volume ratio of about 2:1 to 20:1, and is typically used to remove organic contamination or some metal layers.

Photoresist materials are used in many circuit manufacturing processes to assist in formation of sequential layers. In stages of the manufacturing process, these photoresist materials are often removed, preferably without substantial damage to the substrate, including structures formed thereon. Photoresists are conventionally removed using organic solvents, such as n-methyl-pyrrolidone (“NMP”), glycol ether, amine, or dimethyl sulfoxide (“DMSO”). Alternatively, photoresist materials have been removed using inorganic chemical agents such as sulfuric acid and hydrogen peroxide, or using reactive gaseous chemicals generally known as photoresist plasma ashing. U.S. Pat. No. 5,785,875 discloses a method for removing photoresist material by carrying out a wet acid etch by fully submerging the wafers within anhydrous acid, and draining the etching agent from the chamber while inserting a heated solvent vapor. The solvent is, for example acetone, alcohols, or another solvent, but preferably comprises isopropyl alcohol, and is heated to the range of between about 50° C. and about 100° C. Traditional wet chemical processes used to remove photoresist rely on concentrated sulfuric acid combined with hydrogen peroxide (Piranha or “Sulfuric-Peroxide Mix” or SPM) or ozone (sulfuric-ozone mix or “SOM”). Alternatively, photoresists can be removed under certain conditions by using ozone dissolved in DI water or by mixing ozone gas with water vapor at elevated temperatures.

### SUMMARY OF THE INVENTION

It has been found that removing materials from substrates in the semiconductor industry presents multiple challenges, in particular the development of haze on the substrate after completion of the fabrication process. Material removal processes can lead for example to development of a time dependent haze due to the reaction of chemical residue remaining on the substrate with atmospheric components. This appearance of haze on semiconductor products can lead to significant commercial losses. The problem of haze is particularly an issue when undertaking a selective removal protocol comprising application of acid. It is generally desirable to use a simple process, with the least possible amount of harsh chemicals.

It has been found that a rinsing step following a material removal protocol to provide a treated substrate is surprisingly effective when water vapor is caused to collide with and atomize a stream of rinsing fluid; and the atomized rinsing fluid is caused to rinsingly contact the treated substrate.

The present process is environmentally favorable, because it enables the processing of substrates using smaller amounts of potentially hazardous chemicals as compared to prior art processes. Additionally, the present process may provide favorable results in enhanced selectivity for the overall process, with less haze in the treated product.

### DETAILED DESCRIPTION OF PRESENTLY PREFERRED EMBODIMENTS

The embodiments of the present invention described below are not intended to be exhaustive or to limit the invention to the precise forms disclosed in the following detailed description. Rather a purpose of the embodiments chosen and described is so that the appreciation and understanding by others skilled in the art of the principles and practices of the present invention can be facilitated.

The present method is useful for precision manufacture of substrates where materials, and particularly a photoresist or a silicon nitride film, must be removed. In an embodiment, the substrate is a substrate used in the semiconductor industry, preferably a semiconductor wafer such as a silicon wafer.

In an embodiment, the present process comprises treating the substrate by five major steps, which are as follows:

a) Material removal ->b) Optional Rinse ->
c) Optional Standard Chemical Cleaning Process ->d) Water Vapor Atomized Rinse ->e) Dry

In this embodiment, the rinse steps may use the same or different rinsing fluid and water vapor compositions and application conditions (such as temperature and force).

The material to be removed from the substrate is any material appropriate for removal in the manufacture of semiconductor materials. In an embodiment, the material comprises a photoresist, a hard mask, or a combination thereof.

In embodiments of the present invention, the selective removal protocol includes application of acid. In an embodiment, the acid comprises sulfuric acid, phosphoric acid, or a combination thereof.

In embodiments of the present invention, the material removal step is a selective removal protocol that includes treatment with one or more of the compositions selected from the group consisting of the SC-2 composition (HCl/Peroxide/Water), the Piranha or SPM composition (Sulfuric Acid/Peroxide), SOM (sulfuric acid/ozone) compositions, sulfuric acid compositions, buffered oxide etch (HF and ammonium fluoride) compositions, and NH₄OH, H₃PO₄, HF, HCl or HF/HCl compositions. In a preferred embodiment, the selective removal protocol includes treatment with phosphoric acid.

In embodiments, the substrate is rinsed after the material removal step and before an Optional Standard Chemical Cleaning Process is carried out on the substrate. This optional rinse step may be a conventional immersion rinse, a conventional application of a stream of liquid rinsing fluid to the substrate, or may be a Water Vapor Atomized Rinse step as described in more detail below. In alternative embodiments, the substrate is immediately treated by the Optional Standard Chemical Cleaning Process after the material removal step without an intermediate rinse step.

The Optional Standard Chemical Cleaning Process is any cleaning step such as those known in the art for cleaning undesired material on the surface of the substrate after the initial material removal step. Such Standard Chemical Cleaning Processes include the full strength chemistry treatments known in the art as SC-1, SC-2, SPM, and the like.

The rinsing fluid of the optional rinse and the Water Vapor Atomized Rinse may have the following constitution, which may be the same or different:

In embodiments of the present invention, the rinsing fluid consists essentially of deionized water. In preferred embodiments, the rinsing fluid is hot deionized water (“HDI”). For purposes of the present invention, HDI is at a temperature of from about 40° C. to about 99° C. In embodiments of the present invention, the rinsing fluid consists of deionized water.

In embodiments of the present invention, the rinsing fluid comprises water and any additive chemical component to assist the rinsing of undesired material from the surface of the substrate, provided that the additional component is present only in an amount such that the solution is suitable for use as a final rinse in a process and will not leave deleterious amounts of chemical residues on the surface of the substrate. For example, the rinsing fluid may comprise an acid, base, solvent or surfactant in high dilution, such as a dilution that is greater than 100:1 parts by weight; greater than 1000:1 parts by weight or greater than 10,000:1 parts by weight. In an embodiment, examples of additive chemical components that may be present in the rinsing solution may be selected from hydrochloric acid, sulfuric acid, hydrofluoric acid, phosphoric acid, ozone, peroxide, ammonium hydroxide, isopropyl alcohol (“IPA”), buffering agents and combinations thereof.

In an embodiment, the additive chemical components that may be present in the rinsing solution comprise one or more of NH₄OH, H₂O₂, and IPA. In an embodiment, the rinsing fluid comprises NH₄OH, H₂O₂ and water.

The embodiment wherein the rinsing fluid consists of or consists essentially of water is particularly preferred, because this embodiment is surprisingly effective in removing chemicals from the surface of the substrate while at the same time maintaining the selectivity of the processes carried out on the substrate. This embodiment is particularly effective in cleaning the substrate surface of contaminants while maintaining the selectivity of the entire integrated process.

As noted above, the Water Vapor Atomized Rinse is a special process wherein water vapor to collide with and atomize at least one stream comprising a rinsing fluid, and the atomized rinsing fluid to rinsingly contact the treated substrate.

The Water Vapor Atomized Rinse is surprisingly effective when the rinsing fluid contains only deionized water. In embodiments where the rinsing fluid comprising added chemicals, the Water Vapor Atomized Rinse provides advantages for both equipment and handling considerations. Because energy is provided in the form of the steam of water vapor, the rinsing fluid containing non-water ingredients advantageously does not need to be pre-heated to as high a level prior to dispensing onto a substrate as compared to a rinse process that does not use water vapor. This advantageously reduces the length of time that a chemical-containing composition is heated, for example, in a manner that may cause enhanced chemical challenge to equipment and raise other handling considerations.

For purposes of the present invention, water vapor is defined as water in the gaseous form, and distinguished from small droplets of water commonly called “mist.” Because mist is water that is condensed in the form of small droplets, there is essentially no net warming effect when mist settles on a surface that would correspond to a heat of vaporization. For purposes of the present invention, steam is vaporized water at or above the boiling point of water, which depends on the pressure, e.g. 100° C. if the pressure is 1 atmosphere. When steam is provided at a temperature greater than the boiling point of water, is it called superheated steam.

In an embodiment, the water vapor is provided at a temperature of at least about 100° C. In an embodiment, the water vapor is provided at a temperature of about 130° C.

In an embodiment, the stream of rinsing fluid is caused to collide with water vapor internally in a mixing nozzle. In a preferred embodiment, the stream of rinsing fluid and the water vapor originate from separate orifices and collide externally of a nozzle. In an embodiment, a plurality of streams of rinsing fluid and the water vapor originate from separate orifices and collide externally (i.e. not within a mixing nozzle). In an embodiment, a single stream of rinsing fluid collides with water vapor originating from a plurality of separate orifices collide externally. In an embodiment, the location, direction of the streams and relative force of the streams are selected to preferably provide a directional flow of the resulting atomized rinsing fluid, so that the atomized rinsing fluid is directed to the surface of a substrate.

In one embodiment, the atomized rinsing fluid is caused to rinsingly contact the surface of the substrate at an angle that is perpendicular to the surface of the substrate. In another embodiment, the atomized rinsing fluid is caused to contact the surface of the substrate at an angle of from about 10 to less than 90 degrees from the surface of the substrate. In another embodiment, the atomized rinsing fluid is caused to contact the surface of the substrate at an angle of from about 30 to about 60 degrees from the surface of the substrate. In a preferred embodiment, the substrate is spinning at a rate of about 250 to about 1000 RPMs during contact of the atomized rinsing fluid with the surface of the substrate. The direction of the contact of the atomized rinsing fluid with the substrate may in one embodiment be aligned with concentric circles about the axis of spin of the substrate, or in another embodiment may be partially or completely oriented away from the axis of rotation of the substrate.

In an embodiment, the atomized rinsing fluid that rinsingly contacts the treated substrate is in the form of a constant stream. In an embodiment, the atomized rinsing fluid that rinsingly contacts the treated substrate is in the form of a pulsed stream.

In an embodiment, the atomized rinsing fluid contacts the treated substrate at a velocity of from about 1 to about 100 m/sec with a droplet diameter of from about I to about 150 um as determined by a Phase Doppler Particle Analyzer (PDPA) system.

In an embodiment, the atomized rinsing fluid is dispensed via an array of nozzles (also referred to as a spray bar) mounted above the substrate. The spray bar is a linear arrangement of orifices extending over the radius of the rotating substrate. The liquid and gas or steam streams collide externally from the nozzle in this embodiment.

In an embodiment, the selectively removing step leaves an acid residue on the treated substrate, and the rinsing step provides a substrate with no visible haze 24 hours, and preferably 48 hours, after completion of the rinsing step

In an embodiment, the selectively removing step leaves an acid residue on the treated substrate, and the rinsing step provides a substrate having less than 150 light point (preferably 100, or preferably 50) defects added greater than or equal to 45 nm on an area equivalent to a 300 mm diameter thermally oxidized silicon substrate. In an embodiment the light point defect count is defined by subtracting the light point defects at 0 hours from the count after 24 hours, and preferably the count after 48 hours, after substrate processing is completed. Measurement is with a KLA Tencor Surfscan SP2 unpatterned wafer inspection system with 2 mm edge exclusion. The KLA Tencor Surfscan SP2 is calibrated on a quarterly basic by a KLA Tencor engineer using polystyrene latex spheres to verify the correct sizing of light point defects.

An additional measurement may be performed with Auger Electron Spectroscopy Analysis measuring phosphorous atomic percentage on the acid treated and rinsed substrate. Three areas on the substrate are analyzed: center, 90 mm from the center and 135 mm from the center. In an embodiment, the amount of detectable acid residue by Auger Electron Spectroscopy Analysis of a substrate treated by the process of the present invention using rinsing liquid and water vapor is less than half that of a substrate treated by a like process using only rinsing liquid atomized by nitrogen and without water vapor.

For example, analysis of acid treated and rinsed substrates after one hour verified the substrate treated only with DI water in the rinsing step contained approximately 2 times more phosphorous atomic percent than substrates acid treated and rinsed with hot DI water and steam or substrates acid treated and followed with a conventional SC1 (chemical) step. This indicates the hot DI water and steam rinse process is as effective as a SC1 (chemical) step at removing atomic phosphorous from the substrate surface and rinsing with DI water only is not as effective. Atomic phosphorous is deposited on the wafer surface from the phosphoric acid treatment step. The presence of atomic phosphorous on the substrate surface can result in haze measurable as light point defects detected by the KLA Tencor Surfscan SP2.

In an embodiment, an all wet photoresist removal process consists of a high temperature SPM chemical dispense process followed by the present rinse step, whereby the rinsing fluid comprises NH₄OH, H₂O₂ and water, without an additional clean step after the high temperature SPM chemical dispense.

The present invention may be used, e.g., in single wafer processing applications where the wafers are either moving or fixed, or in batch applications. Alternatively, the method of the present invention may be used to process multiple wafer-like objects simultaneously, as occurs with batches of wafers when being processed in a spray processing tool such as the MERCURY® or ZETA® spray processors commercially available from TEL FSI Inc, Chaska, Minn., or the Magellan® system, also commercially available from TEL FSI Inc, Chaska, Minn.

Various configurations of spray processing systems that may be used are described in U.S. Pat. No. 7,819,984, titled PROCESS FOR TREATMENT OF SUBSTRATES WITH WATER VAPOR OR STEAM; and also in US Patent Application Publication No. 2013/0037511, titled METHOD AND APPARATUS FOR TREATING A WORKPIECE WITH ARRAYS OF NOZZLES, the disclosures of which are incorporated herein by reference.

### EXAMPLES

Representative embodiments of the present invention will now be described with reference to the following examples that illustrate the principles and practice of the present invention.

### Example 1

The addition of steam to hot deionized water (HDI) for rinsing a substrate after acid processing was performed in the Orion™ Single Wafer Cleaning System manufactured by TEL FSI International. The substrate for this example was a 300 mm thermally oxidized silicon wafer commonly used in the semiconductor fabrication industry. The entire acid and rinsing process was contained in one process recipe and performed in a single chamber on the Orion Single Wafer Cleaning System; i.e. dry in, dry out processing. An array of nozzles (also referred to as a spray bar) introduced steam into the HDI flow above the rotating substrate. The process performance was monitored with a KLA Tencor Surfscan SP2 measuring light point defects (LPDs) greater than or equal to 45 nm with 2 mm edge exclusion. An increase in LPDs over time indicates haze is increasing on the substrate surface. Over 100 LPDs added at the 24 and 48 hour monitoring periods when compared to the 0 hour LPD measurement was considered an unacceptable increase. Haze is a direct indication the rinsing process after the acid processing did not sufficiently remove acid from the substrate surface. By this metric, steam and HDI showed equivalent results compared to a SC1 (chemical) step after acid processing.

The use of steam and HDI removed residual phosphoric acid from the wafer surface and prevented haze formation for greater than 48 hours. This result had previously only been achieved by using a cleaning step comprising SC1 (chemical) dispenses. Additionally the use of steam and HDI improves material selectivity on the substrate surface. The acid processing step can expose materials on the substrate surface that will also be etched or removed by a SC1 (chemical) dispense. A steam and HDI rinse after the acid processing will not etch or remove material as a SC1 (chemical) dispense would.

Auger Electron Spectroscopy Analysis measuring phosphorous atomic percentage on the acid treated substrates gives an additional analysis of the wafer surfaces after processing. Three processes were analyzed using this method are as follows.
1. Hot Phosphoric Acid+DI rinses post acid step
2. Hot Phosphoric Acid+DI+HDI and Steam rinses post acid step
3. Hot Phosphoric Acid+DI+SC1 (chemical) step post acid step

Three areas on the substrate were analyzed; center, 90 mm from the center and 135 mm from the center. Analysis of the acid treated and rinsed substrates after one hour verified the substrate treated only with DI rinses (process 1) contained approximately 2 times more phosphorous atomic percent than substrates acid treated and rinsed with hot DI and steam (process 2) or substrates acid treated and followed with a SC1 (chemical) step (process 3). This indicates the hot DI and steam rinse process is as effective as a SC1 (chemical) step at removing atomic phosphorous from the substrate surface and rinsing with DI only is not as effective. An additional measurement at 24 hours by KLA Tencor Surfscan SP2 showed a large increase in LPDs (>1000 at 45nm) for process 1 and Auger Electron Spectroscopy Analysis of the LPDs indicated phosphorous was present in the LPDs. Process 2 and process 3 did not show an increase in LPDs as measured by the KLA Tencor Surfscan SP2 confirming haze was not present. Atomic phosphorous is deposited on the wafer surface from the phosphoric acid treatment step. The increased level of atomic phosphorous on the substrate surface for process 1 measured at one hour coincides with haze measurable as light point defects at 24 hours by the KLA Tencor Surfscan SP2.

As used herein, the terms “about” or “approximately” mean within an acceptable range for the particular parameter specified as determined by one of ordinary skill in the art, which will depend in part on how the value is measured or determined, e.g., the limitations of the sample preparation and measurement system. Examples of such limitations include preparing the sample in a wet versus a dry environment, different instruments, variations in sample height, and differing requirements in signal-to-noise ratios. For example, “about” can mean greater or lesser than the value or range of values stated by 1/10 of the stated values, but is not intended to limit any value or range of values to only this broader definition. For instance, a concentration value of about 30% means a concentration between 27% and 33%. Each value or range of values preceded by the term “about” is also intended to encompass the embodiment of the stated absolute value or range of values. Alternatively, particularly with respect to biological systems or processes, the term can mean within an order of magnitude, preferably within 5-fold, and more preferably within 2-fold, of a value.

Throughout this specification and claims, unless the context requires otherwise, the word “comprise”, and variations such as “comprises” and “comprising”, will be understood to imply the inclusion of a stated integer or step or group of integers or steps but not the exclusion of any other integer or step or group of integer or step. When used herein “consisting of” excludes any element, step, or ingredient not specified in the claim element. When used herein, “consisting essentially of” does not exclude materials or steps that do not materially affect the basic and novel characteristics of the claim. In the present disclosure of various embodiments, any of the terms “comprising”, “consisting essentially of” and “consisting of” used in the description of an embodiment may be replaced with either of the other two terms.

All patents, patent applications (including provisional applications), and publications cited herein are incorporated by reference as if individually incorporated for all purposes. Unless otherwise indicated, all parts and percentages are by weight and all molecular weights are weight average molecular weights. The foregoing detailed description has been given for clarity of understanding only. No unnecessary limitations are to be understood therefrom. The invention is not limited to the exact details shown and described, for variations obvious to one skilled in the art will be included within the invention defined by the claims.

1. A method of treating a substrate, comprising
a) removing material from a substrate using a treatment protocol to provide a treated substrate;
b) introducing at least one stream comprising a rinsing fluid;
c) causing water vapor to collide with and atomize the rinsing fluid; and
d) causing the atomized rinsing fluid to rinsingly contact the treated substrate.

2. The method of claim 1, wherein the treatment protocol is selectively removing material from a substrate.

3. The method of claim 2, wherein the selective removal protocol comprises application of acid.

4. The method of claim 1, wherein the rinsing fluid consists essentially of deionized water.

5. The method of claim 1, wherein the rinsing fluid consists of deionized water.

6. The method of claim 1, wherein the rinsing fluid comprises water and one or more of NH₄OH, H₂O₂, and IPA.

7. The method of claim 1, wherein the rinsing fluid comprises NH₄OH, H₂O₂ and water.

8. The method of claim 1, wherein the material comprises a photoresist, a hard mask, or a combination thereof.

9. The method of claim 1, wherein the acid comprises sulfuric acid, phosphoric acid, or a combination thereof.

10. The method of claim 1, wherein the water vapor is provided at a temperature of at least about 100° C.

11. The method of claim 1, wherein the water vapor is provided at a temperature of about 130° C.

12. The method of claim 1, wherein the stream of rinsing fluid and the water vapor originate from separate orifices.

13. The method of claim 1, wherein the stream of rinsing fluid is a pulsed stream.

14. The method of claim 1, wherein the selectively removing step leaves an acid residue on the treated substrate, and the rinsing step provides a substrate with less than 100 light point defects added greater than or equal to 45 nm on an area equivalent to a 300 mm diameter substrate measured 24 hours after substrate processing is completed.

15. The method of claim 1, wherein the selectively removing step leaves an acid residue on the treated substrate, and the rinsing step provides a substrate with less than 100 light point defects added greater than or equal to 45 nm on an area equivalent to a 300 mm diameter substrate measured 48 hours after substrate processing is completed.
